(19) United States
(12) Patent Application Publication
(10) Pub. No.: US 2014/0060572 A1
(43) Pub. Date: Mar. 6, 2014

(54) PLASMA PROCESSING APPARATUS AND CLEANING METHOD FOR REMOVING METAL OXIDE FILM

(71) Applicant: TOKYO ELECTRON LIMITED, Minato-ku (JP)

(72) Inventors: Chiaki YASUMURO, Yamanashi (JP); Takashi Sakuma, Yamanashi (JP); Osamu Yokoyama, Yamanashi (JP); Hiroyuki Toshima, Yamanashi (JP); Masamichi Hara, Yamanashi (JP); Cheonsoo Han, Yamanashi (JP); Morihiro Takanashi, Yamanashi (JP); Toshiaki Fujisato, Yamanashi (JP)

(73) Assignee: TOKYO ELECTRON LIMITED, Minato-ku (JP)

(21) Appl. No.: 13/975,528

(22) Filed: Aug. 26, 2013

(30) Foreign Application Priority Data
Aug. 30, 2012 (JP) 2012-189656

(51) Int. Cl. H01L 21/02

(52) U.S. Cl. CPC H01L 21/02041
USPC 134/1.2; 156/345.29

(57) ABSTRACT

In a plasma processing apparatus, a mounting table is provided in a processing chamber, and a remote plasma generating unit is configured to generate an excited gas by exiting a hydrogen-containing gas. The remote plasma generating unit has an outlet for discharging the excited gas. A diffusion unit is provided to correspond to the outlet of the remote plasma generating unit and serves to receive the excited gas flowing from the outlet and diffuse the hydrogen active species having a reduced amount of hydrogen ions. An ion filter is disposed between the diffusion unit and the mounting table while being separated from the diffusion unit. The ion filter serves to capture the hydrogen ions contained in the hydrogen active species diffused by the diffusion unit and allow the hydrogen active species having a further reduced amount of hydrogen ions to pass therethrough the mounting table.

### CROSS-REFERENCE TO RELATED APPLICATIONS

This application claims priority to Japanese Patent Application No. 2012-189656 filed on Aug. 30, 2012, the entire contents of which are incorporated herein by reference.

### FIELD OF THE INVENTION

The present invention relates to a plasma processing apparatus and a cleaning method for removing a metal oxide film.

### BACKGROUND OF THE INVENTION

A semiconductor device generally has a semiconductor element and a wiring to the semiconductor element. As for the wiring of the semiconductor apparatus, a multilayer wiring structure formed by filling a metallic material such as copper in a trench or a via hole formed in an interlayer dielectric, a so-called damascene structure, is used, for example. The damascene structure is formed by repeating a process of forming a trench and a via hole in an interlayer dielectric by etching, and a process of filling a metallic material in the trench and the via hole.

A surface of the wiring manufactured by such method is oxidized by processes, so that a metal oxide film is formed on the surface of the wiring. The metal oxide film needs to be removed because it increases an electrical resistance value of the wiring.

Conventionally, an annealing process using H₂ gas, an Ar sputtering process or the like is used to remove the metal oxide film of the wiring. However, the oxide film cannot be sufficiently reduced by the annealing process using H₂ gas, and the removal of the oxide film may be insufficient. Further, the Ar sputtering process damages the interlayer dielectric, i.e., the dielectric film. As a result, a dielectric constant of the interlayer dielectric may be decreased.

Therefore, Japanese Patent Application Publication No. 2011-82536 discloses a method for removing a metal oxide film by reducing the metal oxide film by hydrogen radicals. In the method disclosed in the above-cited reference, the metal oxide film is reduced and removed by introducing an excited hydrogen gas generated by a remote plasma source into a chamber through an ion filter.

Meanwhile, the semiconductor device requires high density wiring and high speed signal processing. Therefore, it is required to further reduce the resistance value of the wiring and the relative permittivity of the interlayer dielectric.

Therefore, it is required to remove a metal oxide film and further reduce damages to a dielectric film around a metal.

### SUMMARY OF THE INVENTION

In accordance with an aspect of the present invention, there is provided a plasma processing apparatus includes a processing chamber, a mounting table, a remote plasma generating unit, a diffusion unit and an ion filter. The mounting table is provided in the processing chamber. The remote plasma generating unit serves to generate an excited gas containing hydrogen active species by exciting a hydrogen-containing gas. The remote plasma generating unit has an outlet for discharging the excited gas. The diffusion unit is provided to correspond to the outlet of the remote plasma generating unit, the diffusion unit serving to receive the excited gas flowing from the outlet and diffuse the hydrogen active species having a reduced amount of hydrogen ions. The ion filter is disposed between the diffusion unit and the mounting table while being separated from the diffusion unit, the ion filter serving to capture the hydrogen ions contained in the hydrogen active species diffused by the diffusion unit and allow the hydrogen active species having a further reduced amount of hydrogen ions to pass therethrough toward the mounting table.

In this plasma processing apparatus, the excited gas is generated by the remote plasma generating unit. The excited gas contains hydrogen ions and hydrogen radicals. The excited gas is irradiated to the diffusion unit, before being irradiated on a substrate to be processed. The hydrogen ions are trapped by the diffusion unit, and the hydrogen active species are diffused, so that the amount of hydrogen ions contained in the diffused hydrogen active species is reduced. The hydrogen active species diffused by the diffusion unit are irradiated to the substrate in a state where the amount of hydrogen ions contained therein has been further reduced by passing through the ion filter. As described above, in this plasma processing apparatus, the hydrogen active species having a considerably reduced amount of hydrogen ions, i.e., the hydrogen radicals, are irradiated to the substrate. As a result, the metal oxide film can be removed and, also, the damages to the dielectric film around the metal can be considerably reduced.

The diffusion unit may be a metallic flat plate connected to a ground potential. In this case, no opening is formed in the diffusion unit, so that the hydrogen active species irradiated to the diffusion unit can reach the ion filter only by diffusion.

The diffusion unit may have a diameter smaller than or equal to 40% of a diameter of the ion filter. In this case, the hydrogen active species diffused by the diffusion unit can relatively uniformly reach the entire region of the ion filter. As a result, the metal oxide film can be relatively uniformly removed from the entire surface of the substrate.

The ion filter may be a metallic plate having one or more slits. Further, each of the slits may have a width greater than or equal to a debye length. When the width of the slits is smaller than the debye length, the slits can be filled with a sheath. As a result, it is difficult for the hydrogen radicals to pass through the slits. In this case, the width of the slits is greater than the debye length, so that the hydrogen radicals easily pass through the slits. As a result, the removal efficiency of the metal oxide film can be improved.

In accordance with another aspect of the present invention, there is provided a cleaning method for removing a metal oxide film surrounded by a dielectric film, including: mounting a substrate having the dielectric film and the metal oxide film on a mounting table provided in a processing chamber; generating an excited gas by exciting a hydrogen-containing gas containing hydrogen active species in a remote plasma generating unit; allowing a diffusion unit to receive the excited gas flowing from an outlet of the remote plasma generating unit and diffuse the hydrogen active species having a reduced amount of hydrogen ions; and allowing an ion filter to capture the hydrogen ions contained in the hydrogen active species diffused by the diffusion unit and supplying the hydrogen active species having a further reduced hydrogen ions through the ion filter to the substrate. In accordance with this method, the hydrogen active species having a considerably reduced amount of hydrogen ions, i.e., the hydrogen radicals, are irradiated to the substrate. As a result, the metal oxide film can be removed and, also, the damages to the dielectric film around the metal can be considerably reduced.

### BRIEF DESCRIPTION OF THE DRAWINGS

FIG. 1 schematically shows a plasma processing apparatus in accordance with an embodiment of the present invention.

FIG. 2 is an enlarged cross sectional view showing a diffusion unit and an ion filter of the embodiment of the present invention.

FIG. 3 is a top view showing the ion filter of the embodiment of the present invention.

FIG. 4 is a cross sectional view taken along line IV-IV of FIG. 3.

FIG. 5 shows a part of a damascene structure as an example of a substrate to be processed.

FIG. 6 is a graph showing a measurement result of an oxygen concentration after cleaning in Test Examples 1 and 2 and Comparative Example 1.

FIG. 7 is a graph showing a measurement result of a relative permittivity of a dielectric film after cleaning in Test Example 3 and Comparative Example 2.

FIG. 8 is a graph showing a measurement result of concentration of O₂, Si and C in a dielectric film after cleaning in Test Examples 4 to 10 and Comparative Example 3.

FIG. 9 is a graph showing uniformity of reduction of a Cu oxide film in Test Examples 11 to 13 and Comparative Example 4.

FIG. 10 is a graph showing a measurement result of a sheet resistance after cleaning in Test Examples 14 to 16 and Comparative Example 5.

FIG. 11 is a graph showing a carbon concentration of a dielectric film after cleaning in Test Examples 17 and 18 and Comparative Example 6.

### DETAILED DESCRIPTION OF THE EMBODIMENTS

Hereinafter, embodiments of the present invention will be described with reference to the accompanying drawings. Further, like reference numerals will be used for like or similar parts in each of the drawings.

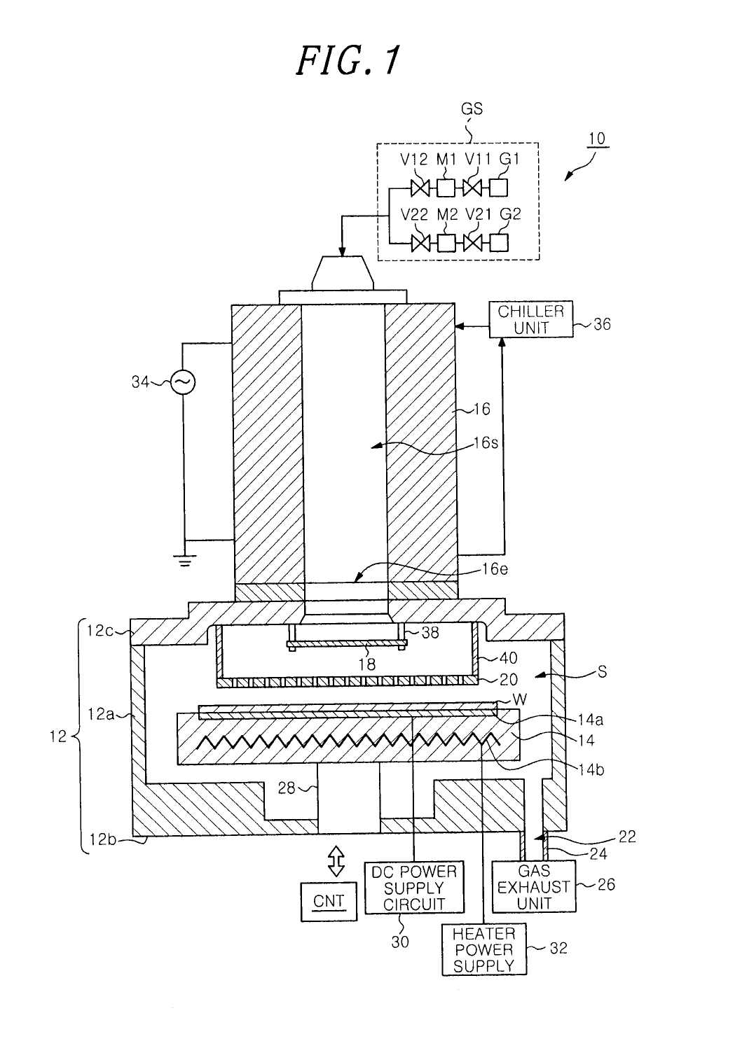

FIG. 1 schematically shows a plasma processing apparatus in accordance with an embodiment of the present invention, and also shows a cross section of the plasma processing apparatus. A plasma processing apparatus 10 shown in FIG. 1 includes a processing chamber 12, a mounting table 14, a remote plasma generating unit 16, a diffusion unit 18, and an ion filter 20.

The processing chamber 12 defines an inner space including a processing space S. The processing chamber 12 is made of a conductor such as aluminum. An oxide film of aluminum, an oxide yttrium film formed by thermal spraying, or the like is formed on inner wall surfaces of the processing chamber 12, which face the inner space. The processing chamber 12 is connected to a ground potential.

In this embodiment, the processing chamber 12 may include a side portion 12a, a bottom portion 12b, and a ceiling portion 12c. The side portion 12a has an approximately cylindrical shape extending in a vertical direction. The bottom portion 12b extends from the lower end of the side portion 12a to define the inner space of the processing chamber 12 at bottom. The ceiling portion 12c is provided on the side portion 12a to close an upper opening of the side portion 12a to define the inner space of the processing chamber 12 at top.

A gas exhaust path 22 is provided at the bottom portion 12b. A gas exhaust unit 26 is connected to the gas exhaust path 22 through a gas exhaust line 24. The gas exhaust unit 26 may include a decompression pump, e.g., a turbo molecular pump, and a pressure controller. The pressure in the inner space of the processing chamber 12 is controlled to a desired level by the gas exhaust unit 26.

A mounting table 14 is provided in the inner space of the processing chamber 12. The aforementioned processing space S is provided above the mounting table 14. In this embodiment, the mounting table 14 is supported by a support 28 extending from the bottom portion 12b in a vertical direction. The mounting table 14 has a function of supporting a substrate W to be processed and controlling a temperature of the substrate W. Specifically, the mounting table 14 includes an electrostatic chuck 14a and a heater 14b. The electrostatic chuck 14a is connected to a DC power supply circuit 30. The electrostatic chuck 14a generates a Coulomb force by a DC voltage applied from the DC power supply circuit 30, and the substrate W is attracted and holed on the electrostatic chuck 14a by the Coulomb force. The heater 14b is embedded in the mounting table 14. The heater 14b is connected to a heater power supply 32, and heat is generated by power supplied from the heater power supply 32 to the heater 14a. The temperature of the substrate to W can be controlled by the heater 14b.

The remote plasma generating unit 16 is provided above the ceiling portion 12c of the processing chamber 12. The remote plasma generating unit 16 generates an excited gas containing hydrogen active species by exciting a hydrogen-containing gas. In this embodiment, the remote plasma generating unit 16 is an inductively coupled plasma source.

In this embodiment, the remote plasma generating unit 16 defines a plasma generation space 16s above the processing space S. Further, the remote plasma generating unit 16 may have a coil surrounding the corresponding plasma generation space 16s. The coil of the remote plasma generating unit 16 is connected to a high frequency power supply 34 for supplying a high frequency power to the corresponding coil. Moreover, a coolant path for controlling a temperature of the corresponding remote plasma generating unit 16 is formed in the remote plasma generating unit 16, and a chiller unit. 36 is connected to the corresponding coolant path.

A gas supply system GS is connected to the plasma generation space 16s of the remote plasma generating unit 16. The gas supply system GS supplies a hydrogen-containing gas into the plasma generation space 16s. In this embodiment, the gas supply system GS includes a gas source G1, a valve V11, a mass flow controller M1, a valve V12, a gas source G2, a valve V21, a mass flow controller M2, and a valve V22.

The gas source G1 is a gas source of H₂ gas, and is connected to the plasma generation space 16s via the valve V11, the mass flow controller M1, and the valve V12. The flow rate of H₂ gas supplied from the gas source G1 into the plasma generation space 16s is controlled by the mass flow controller M1. Further, the gas source G2 is a gas source of a rare gas, Ar gas in this embodiment. The gas source G2 is connected to the plasma generation space 16s via the valve V21, the mass flow controller M2, and the valve V22. The flow rate of Ar gas supplied from the gas source G2 into the plasma generation space 16s is controlled by the mass flow controller M2.

In the remote plasma generating unit 16, a hydrogen-containing gas is supplied to the plasma generation space 16s. Further, an induction field is generated in the plasma generation space 16s by the high frequency power supplied from the high frequency power supply 34. Accordingly, in the plasma generation space 16s, a hydrogen-containing gas is excited, thereby generating an excited gas. Hydrogen active species in the excited gas include hydrogen ions and hydrogen radicals. The remote plasma generating unit 16 has an outlet 16e for the excited gas. In this embodiment, the outlet 16e is provided opposite to the top surface (the electrostatic chuck 14a) of the mounting table 14, i.e., the substrate W), via the opening formed at the ceiling portion 12c of the processing chamber 12 and the processing space S.

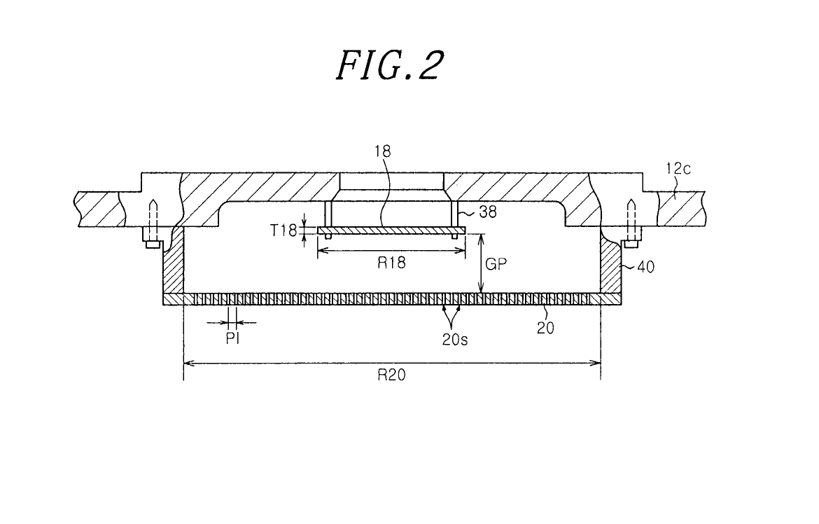

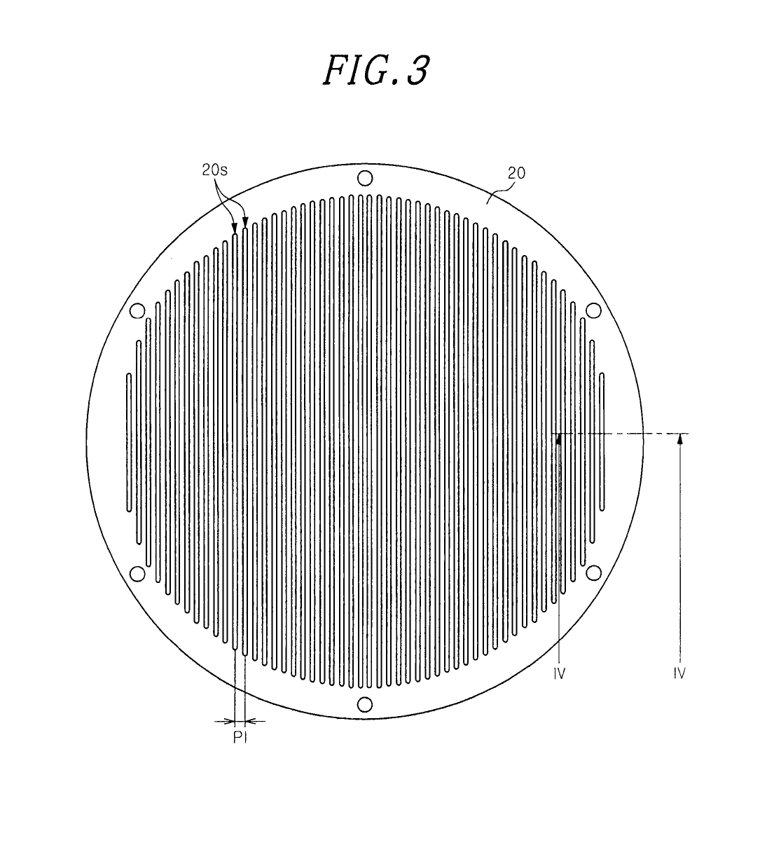

Referring to, FIGS. 2 to 4 together with FIG. 1, a diffusion unit 18 is provided between the outlet 16e and the mounting table 14 to correspond to the outlet 16e. The diffusion unit 18 reduces the amount of hydrogen ions in the hydrogen active species contained in the excited gas discharged from the outlet 16e and diffuses the hydrogen active species having a reduced amount of hydrogen ions. In this embodiment, the diffusion unit 18 is a flat plate made of a metal such as aluminum, and may have a disc shape. Specifically, the diffusion unit 18 has no opening or the like for allowing the hydrogen active species to pass therethrough. The diffusion unit 18 is connected to the ceiling portion 12c of the processing chamber 12 via a holding body 38 made of a conductor such as aluminum. Therefore, the diffusion unit 18 is connected to a ground potential.

The diffusion unit 18 receives the excited gas flowing through the outlet 16e. Since the diffusion unit 18 is connected to a ground potential, the hydrogen ions in the hydrogen active species contained in the excited gas are partially or mostly captured by the diffusion unit 18. Further, the hydrogen radicals in the hydrogen active species contained in the excited gas are reflected by collision with the diffusion unit 18 and diffused to the periphery of the diffusion unit 18.

The ion filter 20 is provided between the diffusion unit 18 and the mounting table 14. Specifically, the ion filter 20 is provided to cover the diffusion unit 18 when viewed from the mounting table 14. Further, the ion filter 20 is provided below the diffusion unit 18 so as to be separated from the diffusion unit 18. The ion filter 20 further reduces the amount of hydrogen ions in the hydrogen active species diffused by the diffusion unit 18 and allows the hydrogen active species having a reduced amount of hydrogen ions to pass therethrough.

In this embodiment, the ion filter 20 is a disc-shaped metallic plate. The ion filter 20 is disposed substantially coaxially and in parallel with the diffusion unit 18. Moreover, the ion filter 20 is disposed below the diffusion unit 18 to be separated from the diffusion unit 18. Accordingly, the hydrogen active species diffused by the diffusion unit 18 may enter the space below the diffusion unit 18. The lower end of a cylindrical supporting part 40 made of a metal is connected to the peripheral edge portion of the ion filter 20, and the upper end of the supporting part 40 is connected to the ceiling portion 12c of the processing chamber 12. Accordingly, the ion filter 20 is connected to a ground potential.

The ion filter 20 has one or more through holes for allowing the hydrogen radicals among the hydrogen active species to pass therethrough. The through holes are formed in the entire region of the ion filter 20 except for the peripheral portion thereof. In this embodiment, a plurality of slits 20s extending from the top surface to the bottom surface of the ion filter 20 is formed at a predetermined pitch in the entire region of the ion filter 20 except for the peripheral portion thereof.

The ion filter 20 captures the hydrogen ions in the hydrogen active species diffused by the diffusion unit 18. The hydrogen radicals in the hydrogen active species diffused by the diffusion unit 18 may pass through the slits 20s of the ion filter 20. Therefore, the hydrogen radicals, passing through that have penetrated the slits 20s, are irradiated to the substrate W.

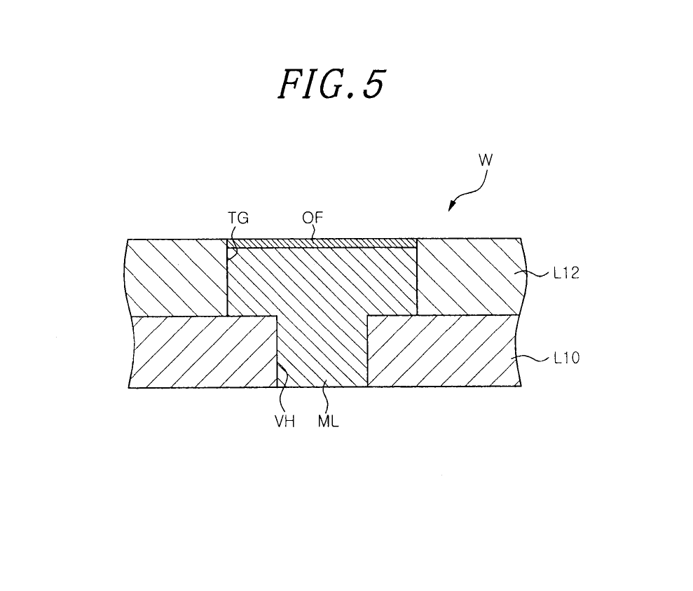

The substrate W has a damascene structure, for example. The damascene structure has a plurality of interlayer dielectrics. The interlayer dielectrics are dielectric films made of a Low-k material, i.e., a low dielectric constant material. FIG. 5 shows a part of the damascene structure as an example of the substrate to be processed. In FIG. 5, interlayer dielectrics L10 and L12 included in the damascene structure are illustrated. The dielectric materials such as the interlayer dielectrics L10 and L12 may have a structure with a straight chain including oxygen and silicon (i.e., Si) in which a methyl group is bonded to Si. An example of the dielectric film is a SiCOH Low-k film.

As shown in FIG. 5, a via hole VH is formed in the interlayer dielectric L10, and a trench TG is formed in the interlayer dielectric L12. The via hole VH and the trench TG may be formed by etching. A wiring ML made of a metal such as Cu is filled in the via hole VH and the trench TG. The damascene structure is obtained by overlapping the structure shown in FIG. 5, and provides a multilayer wiring for a semiconductor device. Here, a metal oxide film OF is formed on the surface of the wiring ML until a separate wiring or a layer such as an interlayer dielectric is formed on the wiring ML.

The plasma processing apparatus 10 can remove the oxide film OF and reduce damages to the interlayer dielectric L12. Hereinafter, the principle of the above and a cleaning method for removing a metal oxide film in accordance with an embodiment of the present invention will be described.

As described above, in the plasma processing apparatus 10, the hydrogen-containing gas is excited by the remote plasma generating unit 16, thereby generating an excited gas. This excited gas passes through the outlet 16e to be received by the diffusion unit 18. Further, the hydrogen ions in the hydrogen active species in the excited gas are partially or mostly captured by the diffusion unit 18, and the hydrogen active species having a reduced amount of hydrogen ions are diffused to the periphery of the diffusion unit 18.

Next, the hydrogen active species diffused by the diffusion unit 18 reach the ion filter 20. The ion filter 20 captures the hydrogen ions contained in the hydrogen active species, so that the amount of the hydrogen ions is further reduced. Further, the ion filter 20 allows the hydrogen active species having a further reduced amount of hydrogen ions to pass therethrough so that the hydrogen active species can be supplied toward the substrate W to be processed.

The oxide film OF is reduced and removed by the hydrogen active species irradiated to the substrate W. Further, the amount of hydrogen ions in the hydrogen active species irradiated to the substrate W is considerably reduced. Accordingly, most of the hydrogen active species irradiated to the substrate W are hydrogen radicals. The hydrogen ions can cleave a methyl group of the interlayer dielectric L12, i.e., the dielectric film. However, the hydrogen radicals can remove the oxide film OF while suppressing cleavage of the methyl group of the dielectric film. Accordingly, the damages to the interlayer dielectric L12 can be reduced and, further, the increase in the relative permittivity of the interlayer dielectric L12 can be suppressed.

As shown in FIG. 1, in this embodiment, the plasma processing apparatus 10 may further include a control unit Cnt. The control unit Cnt may be a controller such as a programmable computer. The control unit Cnt can control each unit of the plasma processing apparatus 10 by a program based on a recipe. For example, the control unit Cnt can control the supply of H₂ gas by transmitting control signals to the valves V11 and V12, and also can control a flow rate of the H₂ gas by transmitting a control signal to the mass flow controller M1. Further, the control unit Cnt can control the supply of a rare gas by transmitting control signals to the valves V21 and V22, and also can control a flow rate of the rare gas by transmitting a control signal to the mass flow controller M2. Furthermore, the control unit Cnt can control a high frequency power, a temperature of the mounting table 14 (i.e., a temperature of the substrate W to be processed), a gas exhaust amount of the gas exhaust unit 26 by transmitting control signals to the gas exhaust unit 26, the heater power supply 32, and the high frequency power supply 34.

In this embodiment, the diffusion unit 18 may have a diameter (see “R18” in FIG. 2) smaller than or equal to 40% of a diameter (see “R20” in FIG. 2) of the ion filter 20. In accordance with the diffusion unit 18 having such diameter, the hydrogen active species are also diffused to the space below the diffusion unit 18. Accordingly, the hydrogen active species can reach the entire region of the ion filter 20. As a result, the hydrogen radicals can be relatively uniformly irradiated to the substrate W.

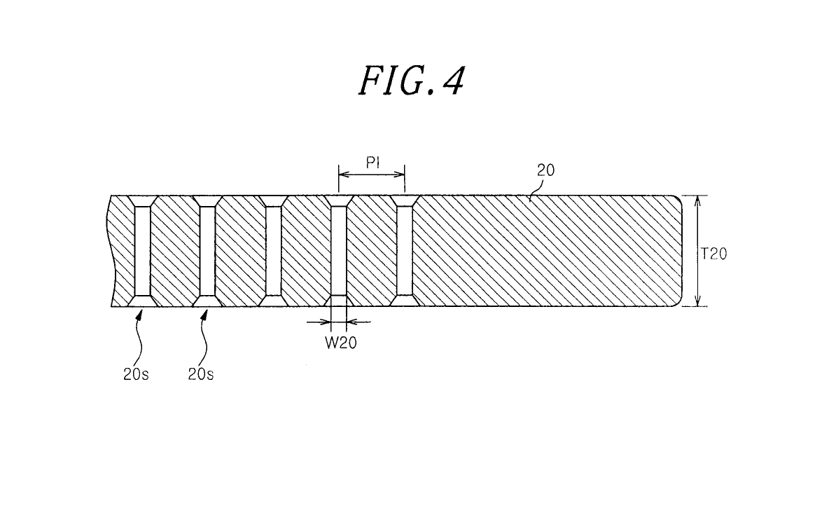

Further, in this embodiment, the slits 20s may have a width greater than or equal to a debye length (see “W20” of FIG. 4). A debye length λ_{D} is defined by the following Eq. (1).

$${λ}_{D} = \sqrt{\frac{{ɛ}_{0} κ {T}_{e}}{{n}_{0} {e}^{2}}} = 7.43 \times {10}^{2} \sqrt{\frac{{T}_{e}}{{n}_{0}}} \qquad ( 1 )$$

Where, ∈ₒ indicates a dielectric constant of vacuum; k indicates a Boltzmann constant; Tₑ indicates an electron temperature; n₀ indicates an electron density; and e indicates an elementary electric charge. In the plasma processing apparatus 10, the electron density n₀ is about 1×10⁸ (cm⁻³), and the electron temperature Tₑ is about 4 (eV). Therefore, in the plasma processing apparatus 10, the debye length λ_{D} is about 1.5 mm, and the slits 20s have a width of about 1.5 mm in this embodiment.

When the width of the slits 20s is smaller than the debye length, the slit 20s are filled with a sheath. As a result, it is difficult for the hydrogen radicals to pass through the slits 20s. Meanwhile, when the width of the slits 20s is greater than or equal to the debye length, hydrogen radicals can easily pass through the slits 20s. As a result, the oxide film OF can be effectively removed.

Hereinafter, the present invention will be described in detail with reference to Test Examples. However, the present invention is not limited to the Test Examples.

### Test Examples 1 and 2 and Comparative Example 1

In Test Examples 1 and 2 and a Comparative Example 1, a substrate to be processed having Cu uniformly formed on one main surface of the substrate having a diameter of 300 mm was prepared, and an oxide film on a Cu surface was removed. In Test Examples 1 and 2, the cleaning using the plasma processing apparatus 10 was performed for about 15 sec and 30 sec, respectively. Other conditions of Test Examples 1 and 2 are described in the following.

<Conditions of Test Examples 1 and 2>

Temperature of the Substrate: 250° C.

Pressure in the processing chamber 12: 400 mTorr (53.55 Pa)

Ar gas flow rate: 110 sccm

H₂ gas flow rate: 13 sccm

High frequency power of the high frequency power supply 34: 2 kW

Frequency of the high frequency power of the high frequency power supply 34: 3 MHz

Diffusion unit 18: diameter 120 mm, thickness (see “T18” in FIG. 2) 6 mm, made of aluminum

Ion filter 20: diameter 300 mm, thickness (see “T20” in FIG. 4) 10 mm, made of aluminum

Slit 20s: width 1.5 mm, pitch (see “PI” in FIG. 4) 4.5 mm

Gap distance between the diffusion unit 18 and the ion filter 20 (see “GP” in FIG. 2): 42.25 mm

In Comparative Example 1, the oxide film on the Cu surface was removed by annealing using H₂ gas. The conditions of Comparative Example 1 are described in the following.

<Conditions of Comparative Example 1>

Temperature of the Substrate: 265° C.

Pressure in the processing chamber: 5.7 Torr (759.9 Pa)

Ar gas flow rate: 0 sccm

H₂ gas flow rate: 1120 sccm

Processing time: 60 sec

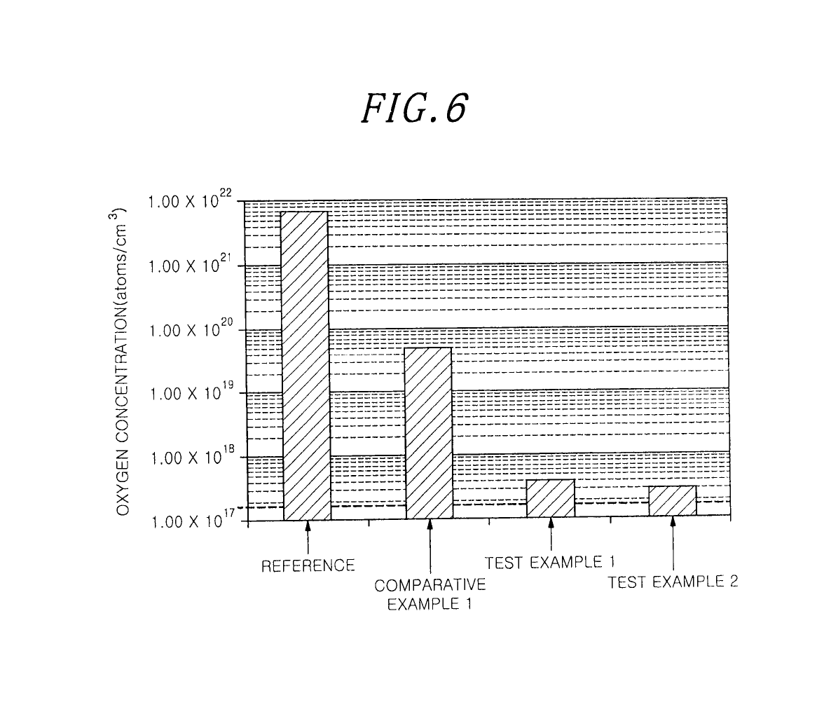

In Test Examples 1 and 2, and Comparative Example 1, the oxygen concentration on the Cu surface of the substrate after the cleaning was measured by using a SIMS (Secondary Ion Mass Spectrometry). The device used for the measurement was ADEPT1010 manufactured by ULVAC PHI, INC. FIG. 6 shows the oxygen concentration on the Cu surface of the substrate after the cleaning in Test Examples 1 and 2, and Comparative Example 1. Further, in FIG. 6, the oxygen concentration on the Cu surface before the cleaning is shown as “Reference”. Moreover, in FIG. 6, the measurement limit of the device used for the measurement is indicted by a dashed line.

As shown in FIG. 6, in Comparative Example 1, a relatively high oxygen concentration was measured on the Cu surface after the cleaning. Accordingly, it was found that the oxide film on the Cu surface was not completely reduced in Comparative Example 1, i.e., in the annealing process using H₂ gas. Meanwhile, in Test Examples 1 and 2, the oxygen concentration close to the measurement limit of the device used for the measurement was measured on the Cu surface after the cleaning. Accordingly, it was found that the cleaning of Test Examples 1 and 2 had a high removal capability of the oxide film on the Cu surface.

### Test Example 3 and Comparative Example 2

In Test Example 3 and Comparative Example 2, a substrate to be processed having a dielectric film uniformly formed on a main surface of the substrate having a diameter of 300 mm was prepared and cleaning was performed. As for a dielectric film, a SiCOH Low-k was used. The thickness of the dielectric film was 150 nm. The conditions of Test Example 3 are described in the following.

<Conditions of Test Example 3>

Temperature of the substrate: 250° C.

Pressure in the processing chamber 12: 400 mTorr (53.55 Pa)

Ar gas flow rate: 110 sccm

H₂ gas flow rate: 13 sccm

High frequency power of the high frequency power supply 34: 2 kW

Frequency of the high frequency power of the high frequency power supply 34: 3 MHz

Diffusion unit 18: diameter 120 mm, thickness 6 mm, made of aluminum

Ion filter 20: diameter 300 mm, thickness 10 mm, made of aluminum

Slit 20s: width 1.5 mm, pitch 4.5 mm

Gap distance between the diffusion unit 18 and the ion filter 20: 42.25 mm

Processing time: 30 sec

The cleaning conditions of Comparative Example 2 were the same as those of Test Example 3 except that the diffusion unit 18 and the ion filter 20 are omitted in the plasma processing apparatus 10.

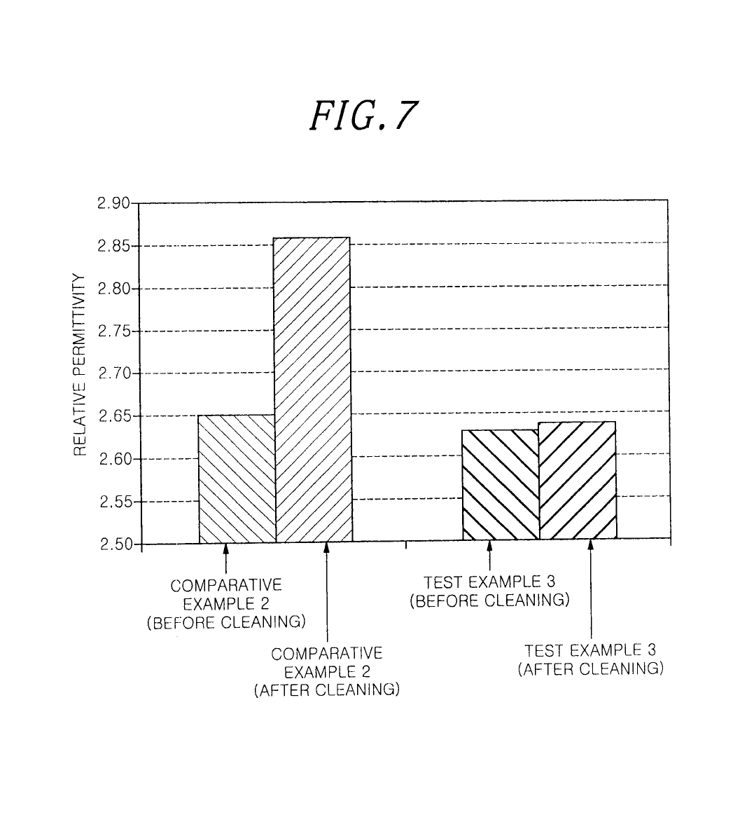

In Test Example 3 and Comparative Example 2, the relative permittivity of the dielectric film before and after the cleaning was measured by a mercury probe method. The result thereof is shown in FIG. 7. As shown in FIG. 7, in Comparative Example 2, i.e., in the case where the diffusion unit 18 and the ion filter 20 were removed, the relative permittivity of the dielectric film after the cleaning was considerably increased compared to that of the dielectric film before the cleaning. Meanwhile, in Test Example 3, the relative permittivity of the dielectric film after the cleaning was substantially the same as that of the dielectric film before the cleaning. From this, it was found that the dielectric film was substantially not damaged by the cleaning of Test Example 3.

### Test Examples 4 to 10 and Comparative Example 3

In Test Examples 4 to 10 and Comparative Example 3, a substrate having a dielectric film uniformly formed on one main surface of the substrate having a diameter of 300 mm was prepared and cleaning was performed. As for the dielectric film, a SiCOH Low-k film was used. The thickness of the dielectric film was 150 nm. In Test Examples 4 to 7, the power of the high frequency power supply 34 was varied. In Test Examples 8 to 10, the flow rates of Ar gas and H₂ gas were varied. The conditions of Test Examples 4 to 10 are described in the following.

<Conditions of Test Examples 4 to 10>

Temperature of the substrate: 250° C.

Pressure in the processing chamber 12: 400 mTorr (53.55 Pa)

Ar gas flow rate in Test Examples 4 to 7: 110 sccm

H₂ gas flow rate in Test Examples 4 to 7: H₂ gas flow rate: 13 sccm

High frequency power of the high frequency power supply 34 in Test Examples 4 to 7: 1 kW, 1.5 kW, 2 kW, 2.5 kW

Ar gas flow rate in Test Examples 8 to 10: 55 sccm, 110 sccm, 220 sccm

H₂ gas flow rate in Test Examples 8 to 10: H₂ gas flow rate: 6 sccm, 13 sccm, 26 sccm

High frequency power of the high frequency power supply 34 in Test Examples 8 to 10: 2 kW

Frequency of the high frequency power of the high frequency power supply 34: 3 MHz

Diffusion unit 18: diameter 120 mm, width 6 mm, made of aluminum

Ion filter 20: diameter 300 mm, width 10 mm, made of aluminum

Slit 20s: width 1.5 mm, pitch 4.5 mm

Gap distance between the diffusion unit 18 and the ion filter 20: 42.25 mm

Processing time: 30 sec

The cleaning conditions of Comparative Example 3 were the same as those of Test Example 6 except that the diffusion unit 19 and the ion filter 20 were omitted in the plasma processing apparatus 10.

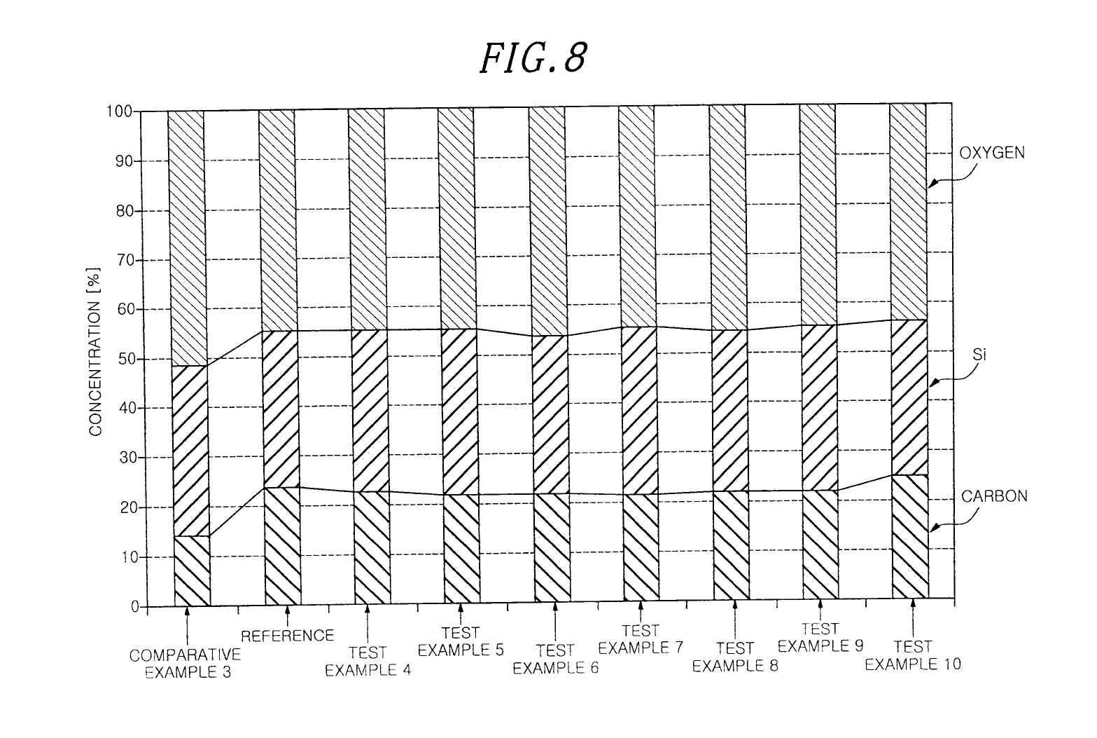

In Test Examples 4 to 10 and Comparative Example 3, the concentration of O₂, Si and C of the dielectric film after the cleaning was measured by Ar-XPS (Angle Resolved XPS). The device used for the measurement was Theta Probe manufactured by Thermo Fisher Scientific. FIG. 8 shows the concentration of O₂, Si and C of the dielectric film after the cleaning in Test Examples 4 to 10 and Comparative Example 3. Further, in FIG. 8, an example of the concentration of O₂, Si and C of the dielectric film before the cleaning is shown as “reference”

As shown in FIG. 8, in Comparative Example 3, i.e., in the case where the diffusion unit 18 and the ion filter 20 were removed, the carbon concentration of the dielectric film after the cleaning was considerably decreased compared to that of the dielectric film before the cleaning. This shows that the methyl group in the dielectric film is cleaved. Meanwhile, in Test Examples 4 to 10, the carbon concentration of the dielectric film after the cleaning was not greatly different from that of the dielectric film before the cleaning. From this, it has been found that the damages to the dielectric film are reduced in the cleaning of Test Examples 4 to 10. Further, it has been found from the result of the cleaning of Test Examples 4 to 10 that, even if the power of the high frequency power supply 34 and the flow rates of H₂ gas and Ar gas are changed, the relative permittivity of the dielectric film is not greatly changed. This shows that the relative permittivity of the dielectric film has low dependency to the power of the high frequency power supply 34 and the flow rates of H₂ gas and Ar gas in the cleaning process.

### Test Examples 11 to 13 and Comparative Example 4

In Test Examples 11 to 13 and the Comparative Example 4, a substrate having Cu uniformly formed on one main surface of the substrate having a diameter of 300 mm was prepared and cleaning was performed. In Test Examples 11 to 13 and Comparative Example 4, the thickness of the Cu oxide film was 30 nm. In Test Examples 11 to 13, the diameters of the diffusion unit 18 were set to about 90 mm, 120 mm, and 160 mm, respectively. Further, in Comparative Example 4, the diffusion unit 18 was removed. In other words, in Comparative Example 4, the diameter of the diffusion unit 18 was set to 0 mm. Other conditions of Test Examples 11 to 13 and Comparative Example 4 are described in the following.

<Conditions of Test Examples 11 to 13 and Comparative Example 4>

Temperature of the substrate: 250° C.

Pressure in the processing chamber 12: 400 mTorr (53.55 Pa)

Ar gas flow rate: 110 sccm

H₂ gas flow rate: 13 sccm

High frequency power of the high frequency power supply 34: 2 kW

Frequency of the high frequency power of the high frequency power supply 34: 3 MHz

Diffusion unit 18: thickness 6 mm, made of aluminum Ion filter 20: diameter 300 mm, thickness 10 mm, made of aluminum Slit 20s: width 1.5 mm, pitch 4.5 mm

Gap distance between the diffusion unit 18 and the ion filter 20: 42.25 mm

Processing time: 120 sec

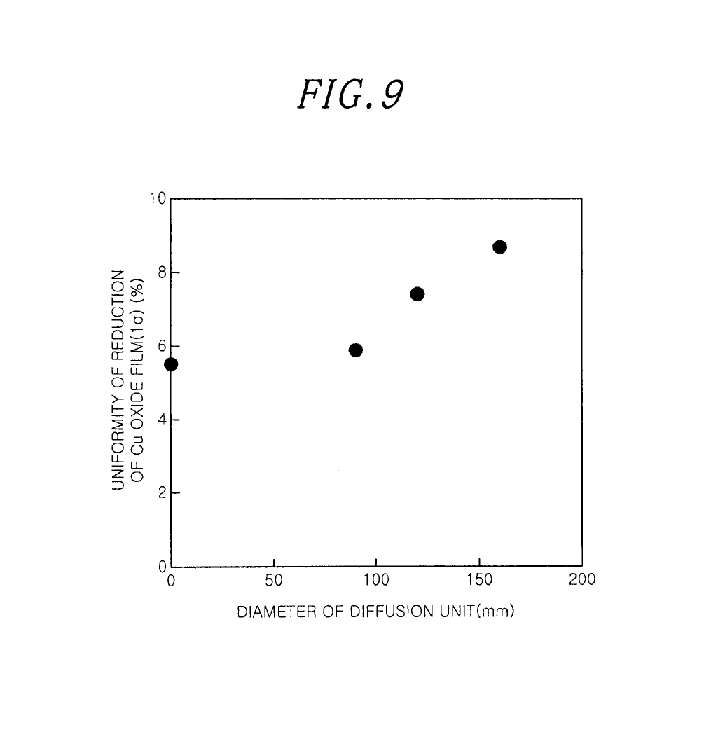

In Test Examples 11 to 13 and Comparative Example 4, reduction of a Cu oxide film was evaluated by using a sheet resistance measured by a 4-point probe method. Specifically, in Test Examples 11 to 13 and Comparative Example 4, an in-plane sheet resistance of the substrate having a diameter of about 300 mm was measured at 49 points, and a deviation 1σ of the measured sheet resistances at the 49 points was obtained. The device used for the measurement of the sheet resistance was VR300DSE manufactured by HITACHI KOKUSAI DENKI ENGINEERING CO., LTD. Further, the 49 points for measurement were arranged in concentric circles radially spaced at a distance of 49 mm, 98 mm and 147 mm from the center of the substrate. In other words, in Test Examples 11 to 13 and Comparative Example 4, the sheet resistance was measured under the same reduction processing conditions (power of high frequency power supply, processing time and the like) except for the presence or absence of the diffusion unit and the different diameters of the diffusion units and, then, the deviation 1σ was obtained. FIG. 9 shows the evaluation result of the reduction uniformity of the Cu oxide film in Test Examples 11 to 13 and Comparative Example 4. Specifically, FIG. 9 shows a deviation (1σ) of the sheet resistance in Test Examples 11 to 13 and Comparative Example 4. As can be clearly seen from FIG. 9, the deviation in the reduction of the Cu oxide film is decreased as the diameter of the diffusion unit 18 is decreased.

### Test Examples 14 to 16 and Comparative Example 5

In Test Examples 14 to 16 and Comparative Example 5, a substrate having Cu uniformly formed on one main surface of the substrate having a diameter of 300 mm was prepared and an oxide film on a Cu surface was removed. In Test Examples 14 to 16, the diameter of the diffusion unit 18 was set to 90 mm, 120 mm, and 160 mm, respectively. Further, in Comparative Example 5, the diffusion unit 18 was removed. In other words, in Comparative Example 5, the diameter of the diffusion unit 18 was set to 0 mm. Other conditions of Test Examples 14 to 16 and Comparative Example 5 are described in the following.

<Conditions of Test Examples 14 to 16 and Comparative Example 5>

Temperature of the substrate: 250° C.

Pressure in the processing chamber 12: 400 mTorr (53.55 Pa)

Ar gas flow rate: 110 sccm

H₂ gas flow rate: 13 sccm

High frequency power of the high frequency power supply 34: 2 kW

Frequency of the high frequency power of the high frequency power supply 34: 3 MHz

Diffusion unit 18: thickness 6 mm, made of aluminum

Ion filter 20: diameter 300 mm, thickness 10 mm, made of aluminum

Slit 20s: width 1.5 mm, pitch 4.5 mm

Gap distance between the diffusion unit 18 and the ion filter 20: 42.25 mm

Processing time: 240 sec

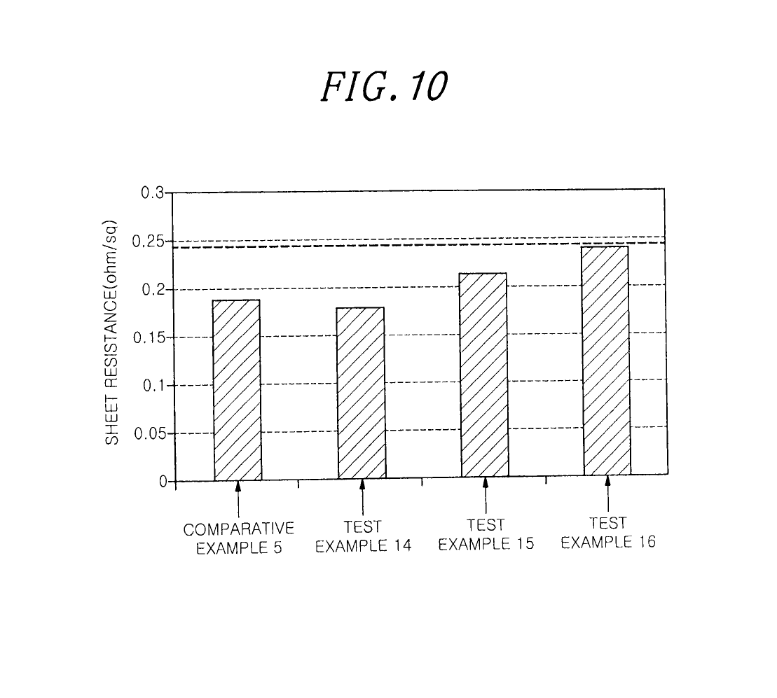

In Test Examples 14 to 16 and Comparative Example 5, the sheet resistance of Cu at the center of the substrate after the cleaning was measured. The result thereof is shown in FIG. 10. Further, the dashed line in FIG. 10 indicates the sheet resistance at the center of the substrate in a state where the Cu oxide film was not removed. As shown in FIG. 10, in Test Example 16, i.e., in the case of using the diffusion unit 18 having a diameter of 160 mm, the sheet resistance at the center of the substrate was close to that of the Cu oxide film. Meanwhile, in the case of using the diffusion unit 18 having a diameter of 120 mm, the sheet resistance at the center of the substrate was considerably smaller than that of the Cu oxide film. As described above, since the diameter of the ion filter 20 was 300 mm, it has been found, from Test Examples 14 to 16 and Test Examples 11 to 13 described above, the Cu oxide film was uniformly reduced and removed in the entire region of the substrate by setting the diameter of the diffusion unit 18 to be smaller than or equal to 40% of the diameter of the ion filter 20.

### Test Examples 17 and 18 and Comparative Example 6

In Test Examples 17 and 18 and Comparative Example 6, a substrate having a dielectric film uniformly formed on one main surface of the substrate having a diameter of 300 mm was prepared and cleaning was performed. As for the dielectric film, Black Diamond 2 (Registered Trademark) manufactured by APPLIED MATERIALS, INCORPORATED was used. The thickness of the dielectric film was 150 nm. In Test Examples 17 and 18, the diffusion unit 18 was set to 90 mm and 120 mm, respectively. Further, in Comparative Example 6, the diffusion unit 18 was removed. In other words, in Comparative Example 6, the diameter of the diffusion unit 18 was set to 0 mm. The conditions of Test Examples 17 and 18 and Comparative Example 6 are described in the following.

<Conditions of Test Examples 17 and 18 and Comparative Example 6>

Temperature of the substrate: 250° C.

Pressure in the processing chamber 12: 400 mTorr (53.55 Pa)

Ar gas flow rate: 110 sccm

H₂ gas flow rate: 13 sccm

High frequency power of the high frequency power supply 34: 2 kW

Frequency of the high frequency power of the high frequency power supply 34: 3 MHz

Diffusion unit 18: thickness 6 mm, made of aluminum

Ion filter 20: diameter 300 mm, thickness 10 mm, made of aluminum

Slit 20s: width 1.5 mm, pitch 4.5 mm

Gap distance between the diffusion unit 18 and the ion filter 20: 42.25 mm

Processing time: 15 sec

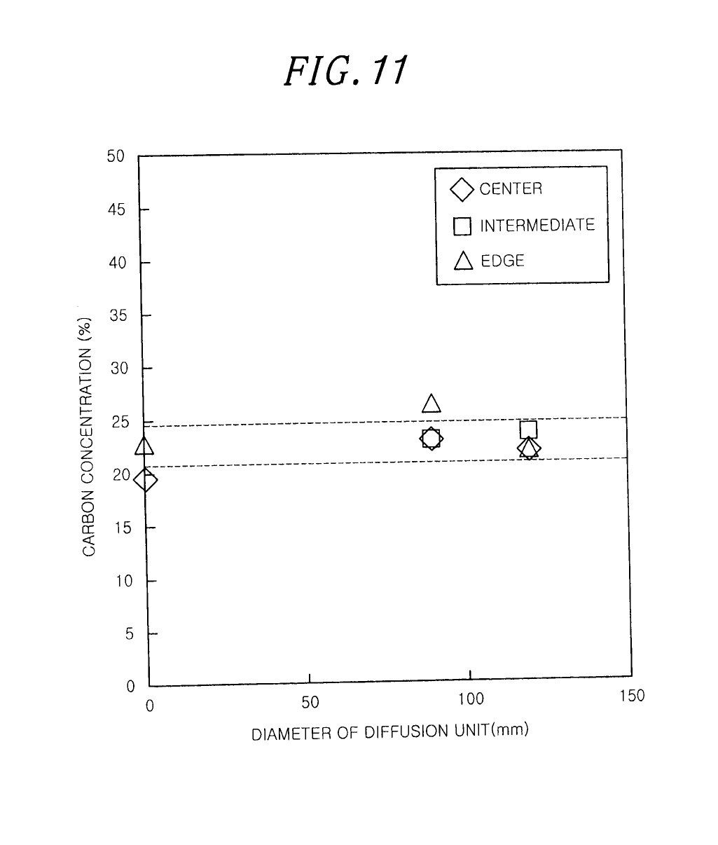

The carbon concentration of the dielectric film after the cleaning in Test Examples 17 and 18 and Comparative Example 6 was measured at the center of the substrate, at a position near the edge, and at an intermediate position between the center and the edge by using Ar-XPS (Angle Resolved XPS). The device used for measurement was Theta Probe manufactured by Thermo Fisher Scientific. The result thereof is shown n FIG. 11. FIG. 11 shows carbon concentration of the dielectric film after the cleaning in Test Examples 17 and 18 and Comparative Example 6. Further, in FIG. 11, a region disposed between two dashed lines indicates a range of carbon concentration of the dielectric film in the case of not performing the cleaning.

As shown in FIG. 11, in the cases of using diffusion units 18 having diameters of 90 mm and 120 mm, the carbon concentration of the dielectric film after the cleaning was not decreased from the carbon concentration of the dielectric film in the case of not performing the cleaning. Accordingly, it has been found from Test Examples 14 to 16, Test Examples 11 to 13, and Test Examples 17 and 18 that the Cu oxide film was uniformly reduced in the entire region of the substrate without damaging the dielectric film by using the diffusion unit 18 having a diameter that is 30% to 40% of the diameter of the ion filter 20.

While the invention has been shown and described with respect to the embodiments, various changes and modification may be made without being limited to the aforementioned embodiments. For example, in the aforementioned embodiments, the inductively coupled plasma source is used as the plasma source of the remote plasma generating unit. However, as for the plasma source, various plasma sources such as a parallel plate type plasma source, a plasma source using a microwave and the like may be used.

What is claimed is:

1. A plasma processing apparatus comprising:
a processing chamber;
a mounting table provided in the processing chamber;
a remote plasma generating unit configured to generate an excited gas containing hydrogen active species by exciting a hydrogen-containing gas, the remote plasma generating unit having an outlet for discharging the excited gas;
a diffusion unit provided to correspond to the outlet of the remote plasma generating unit, the diffusion unit serving to receive the excited gas flowing from the outlet and diffuse the hydrogen active species having a reduced amount of hydrogen ions; and
an ion filter disposed between the diffusion unit and the mounting table while being separated from the diffusion unit, the ion filter serving to capture the hydrogen ions contained in the hydrogen active species diffused by the diffusion unit and allow the hydrogen active species having a further reduced amount of hydrogen ions to pass therethrough toward the mounting table.

2. The plasma processing apparatus of claim 1, wherein the diffusion unit is a metallic flat plate connected to a ground potential.

3. The plasma processing apparatus of claim 2, wherein the diffusion unit has a diameter smaller than or equal to 40% of a diameter of the ion filter.

4. The plasma processing apparatus of claim 1, wherein the ion filter is a metallic plate having one or more slits.

5. The plasma processing apparatus of claim 4, wherein each of the slits has a width greater than or equal to a debye length.

6. A cleaning method for removing a metal oxide film surrounded by a dielectric film, comprising:
mounting a substrate having the dielectric film and the metal oxide film on a mounting table provided in a processing chamber;
generating an excited gas by exciting a hydrogen-containing gas containing hydrogen active species in a remote plasma generating unit;
allowing a diffusion unit to receive the excited gas flowing from an outlet of the remote plasma generating unit and diffuse the hydrogen active species having a reduced amount of hydrogen ions; and
allowing an ion filter to capture the hydrogen ions contained in the hydrogen active species diffused by the diffusion unit and supplying the hydrogen active species having a further reduced amount of hydrogen ions through the ion filter to the substrate.

7. The method of claim 6, wherein the diffusion unit is a metallic flat plate connected to a ground potential.

8. The method of claim 7, wherein the diffusion unit has a diameter smaller than or equal to 40% of a diameter of the ion filter.

9. The method of claim 6, wherein the ion filter is a metallic plate having one or more slits.

10. The method of claim 9, wherein each of the slits has a width greater than or equal to a debye length.
